(19) United States
(12) Patent Application Publication
(10) Pub. No.: US 2011/0186339 A1
(43) Pub. Date: Aug. 4, 2011

(54) PRINTED CIRCUIT BOARD WITH CARBON NANOTUBE BUNDLE

(75) Inventors: YAO-WEN BAI, Huaian (CN); PAN TANG, Huaian (CN); XIAO-PING LI, Huaian (CN)

(73) Assignees: Hong Heng Sheng Electronical Technology (HuaiAn)Co., Ltd, Huai An City (CN); FOXCONN ADVANCED TECHNOLOGY INC., Tayuan (TW)

(21) Appl. No.: 12/795,839

(22) Filed: Jun. 8, 2010

(30) Foreign Application Priority Data
Jan. 30, 2010 (CN) 201010300948.0

(51) Int. Cl. H05K 1/00

(52) U.S. Cl. 174/258

(57) ABSTRACT

A printed circuit board includes a composite layer, a first electrically conductive pattern, and a second electrically conductive pattern. The composite layer includes a polymer matrix and an electrically conductive pin embedded therein. The polymer matrix has a first surface and an opposite second surface. The pin includes a catalyst block and a carbon nanotube bundle grown on the catalyst block. The catalyst block is exposed at the first surface, and the carbon nanotube bundle is exposed at the second surface. The first pattern is formed on the first surface, and includes a first electrical contact, which is electrically coupled to the catalyst block. The second pattern is formed on the second surface, and includes a second electrical contact, which is electrically coupled to the carbon nanotube bundle.

### CROSS-REFERENCE TO RELATED APPLICATIONS

This application is related to commonly-assigned co-pending applications application Ser. No. 12/468,841 entitled, “CIRCUIT SUBSTRATE FOR MOUNTING ELECTRONIC COMPONENT AND CIRCUIT SUBSTRATE ASSEMBLY HAVING SAME”, filed on the 19th of May 2009, and application Ser. No. 12/471,396 entitled, “CIRCUIT SUBSTRATE FOR MOUNTING ELECTRONIC COMPONENT AND CIRCUIT SUBSTRATE ASSEMBLY HAVING SAME”, filed on the 24th of May 2009. Disclosures of the above identified applications are incorporated herein by reference.

### BACKGROUND

1. Technical Field

The present disclosure relates to circuit substrate, particularly to a printed circuit board with carbon nanotube bundles.

2. Description of Related Art

Printed circuit boards (PCBs) are widely used in various electronic devices such as mobile phones, printing heads, and hard disk drives for having electronic components mounted thereon and providing electrical transmission. With the development of electronic technology, multilayer PCBs frequently replace single sided or double sided PCBs.

A multilayer PCB generally includes several electrically conductive layers and several insulation layers. Each of the insulation layers is positioned between two neighboring electrically conductive layers. The electrically conductive layers electrically communicate with each other by plated through holes, which penetrate through the multilayer PCB. However, the electrical conductivity of the plated through holes is not as good as in the electrically conductive layers. Therefore, the electrical property of the PCB is affected.

Therefore, to overcome the described limitations, it is desirable to provide a PCB having improved electrical conductivity.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a cross sectional view of a PCB in accordance with a first embodiment.

FIG. 2 is a cross sectional view of a first electrically conductive layer.

FIG. 3 is similar to FIG. 2, but showing a number of catalyst blocks formed on the first electrically conductive layer.

FIG. 4 is similar to FIG. 3, but showing a number of carbon nanotube (CNT) bundles grown on the catalyst blocks.

FIG. 5 is similar to FIG. 4, but showing a polymer matrix spread on the first electrically conductive layer thereby forming a composite layer.

FIG. 6 is similar to FIG. 5, but showing a second electrically conductive layer adhered on the composite layer.

FIG. 7 is a cross sectional view of a PCB in accordance with a second embodiment.

### DETAILED DESCRIPTION

Embodiments will now be described in detail below and with reference to the drawings.

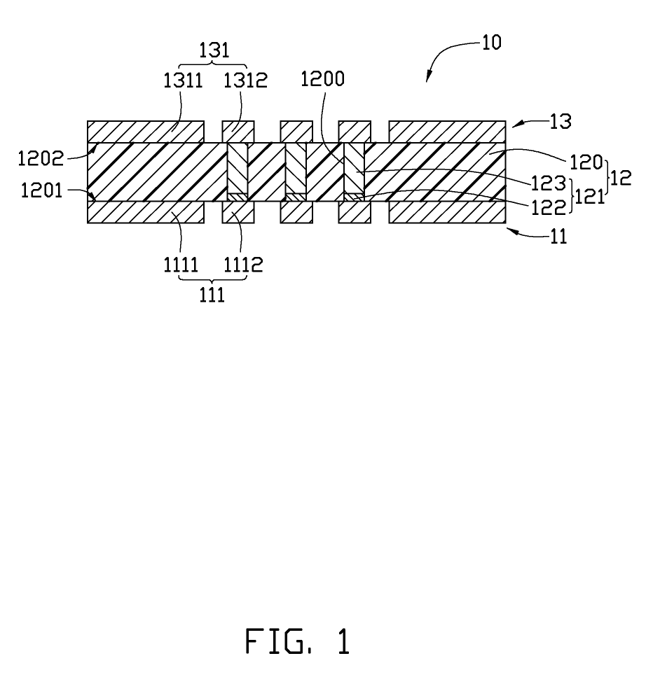

FIG. 1 illustrates a PCB 10 in accordance with a first embodiment. The PCB 10 includes a first electrically conductive layer 11, a composite layer 12, and a second electrically conductive layer 13.

The first layer 11 can be a metal layer, for example, a copper layer with a thickness approximately in a range from 10 micrometers (μm) to 70 μm. The first layer 11 has a first electrically conductive pattern 111 formed therein. The first pattern 111 includes a number of first electrical traces 1111 configured for transmitting electrical signals and at least one first electrical contact 1112 electrically communicating with at least one of the first traces 1111. In the illustrated embodiment, the first pattern 111 includes three equidistantly spaced first contacts 1112 in a central portion of the first layer 11, as shown in FIG. 1.

The second layer 13 can be a metal layer with a structure corresponding to the first layer 11. That is, the shape and size of the second layer 13 is similar to that of the first layer 11. The second layer 13 has a second electrically conductive pattern 131 formed therein. The second pattern 131 includes a number of second electrical traces 1311 configured for transmitting electrical signals and at least one second electrical contact 1312 electrically communicating with at least one of the second traces 1311. The at least one second contact 1312 corresponds to the at least one first contact 1112. That is, the number of the at least one second contact 1312 is equal to the number of the at least one first contact 1112, the distribution of the at least one second contact 1312 corresponds to that of the at least one first contact 1112. In the illustrated embodiment, the second pattern 131 correspondingly includes three equidistantly spaced second contacts 1312 in a central portion of the second layer 13.

The composite layer 12 is positioned between and in contact with the first and second layers 11, 13. The composite layer 12 includes a polymer matrix 120 and at least one electrically communicating pin 121 embedded in the polymer matrix 120.

Specifically, the matrix 120 is a base film with at least one through hole 1200 defined therein. A cross section of the matrix 120 is substantially similar to that of the first layer 11. A material of the matrix 120 can be polyimide, polyethylene terephthalate, polytetrafluoroethylene, polyamide, polymethylmethacrylate, polycarbonate, glass fiber/resin compound, or other material. A thickness of the matrix 120 is in the range from about 20 μm to about 2 millimeters (mm). The matrix 120 has a first surface 1201 contacting the first layer 11 and a second surface 1202 contacting the second layer 13. The at least one through hole 1200 corresponds to the at least one first contact 1112 and the at least one second contact 1312, and is exposed at both the first and second surfaces 1201, 1202. The at least one through hole 1200 is configured for accommodating the at least one communicating pin 121, which is capable of electrically communicating the at least one first contact 1112 with the at least one second contact 1312. In other words, the number of the at least one conductive pin 121 is equal to the number of the at least one through hole 1200 and the number of the at least one second contact 1312. In the illustrated embodiment, the composite layer 12 correspondingly includes three conductive pins 121, and the matrix 120 has three equidistantly through holes 1200 defined in a central portion thereof.

Each of the conductive pins 121 is positioned in a corresponding through hole 1200, and is isolated from other conductive pins 121 by the matrix 120. An end of each conductive pin 121 is exposed at the first surface 1201 and electrically communicates with a corresponding first contact 1112, the other end of each conductive pin 121 is exposed at the second surface 1202 and electrically communicates with a corresponding second contact 1312, thus, each conductive pin 121 functions as a plated through hole to electrically connect the first and second patterns 111, 131 to each other. A length of each conductive pin 121 is substantially the same or longer than a distance between the first surface 1201 and the second surface 1202. Generally, the length of each of the conductive pins 121 is from about 20 μm to about 2 mm.

Each conductive pin 121 includes a catalyst block 122 and a CNT bundle 123 grown on the catalyst block 122. Each catalyst block 122 is exposed at the first surface 1201 and electrically communicates with a corresponding first contact 1112. Each CNT bundle 123 is exposed at the second surface 1202 and electrically communicates with a corresponding second contact 1312. A cross section of the catalyst blocks 122 is similar to that of the CNT bundles 123. In the illustrated embodiment, the catalyst blocks 122, the CNT bundles 123, the first contacts 1112, and the second contacts 1312 each have a circular cross section, with the catalyst blocks 122 each being coaxial with a corresponding CNT bundle 123, and the diameter of the first contacts 1112 being equal to that of the second contacts 1312, and larger than that of the CNT bundles 123. A material of the catalyst blocks 122 comprises iron, cobalt, nickel, or alloy thereof. A thickness of each of the catalyst blocks 122 is in a range from about 1 nanometer (nm) to 50 nm. The CNT bundles 123 each include a number of substantially parallel CNTs, and extend from the catalyst block 122 to the second surface 1202 inclined at an angle from 80° to 100° relative to the second surface 1202. In other words, the CNT bundles 123 as well as the conductive pins 121 are substantially parallel to each other and substantially perpendicular to the second surface 1202.

It is noted that one second contact 1312 can be electrically in contact with one or more conductive pins 121, but one conductive pin 121 can just be electrically in contact with one second contact 1312. Therefore, electrical signals transmitted in the respective second contacts 1312 will not be interfered with by the conductive pins 121.

It is also noted that the number and distribution of the conductive pins 121 can be varied according to practical need, for example, the conductive pins 121 can be distributed non-uniformly at a peripheral portion of the composite layer 12.

In the illustrated PCB 10, due to the CNT bundles 123 having excellent electrical conductivity along central axes thereof, the conductive pins 121 in the composite layer 12 have excellent electrical conductivity to transmit electrical signals from the first layer 11 to the second layer 13.

The PCB 10 can be manufactured by the following steps.

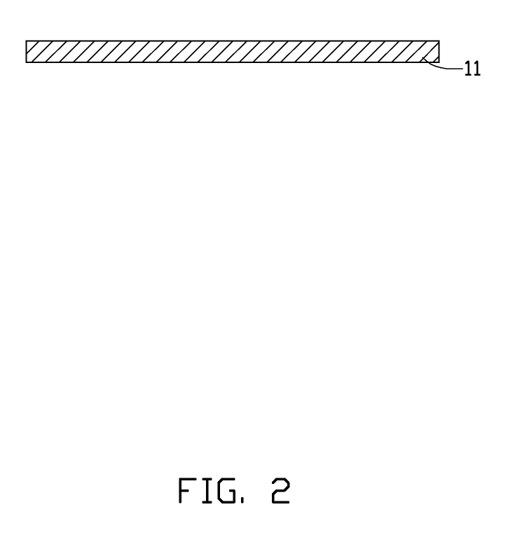

In step 1, referring to FIG. 2, the first layer 11 is provided. The first layer 11 can be metal such as copper, silver, and nickel.

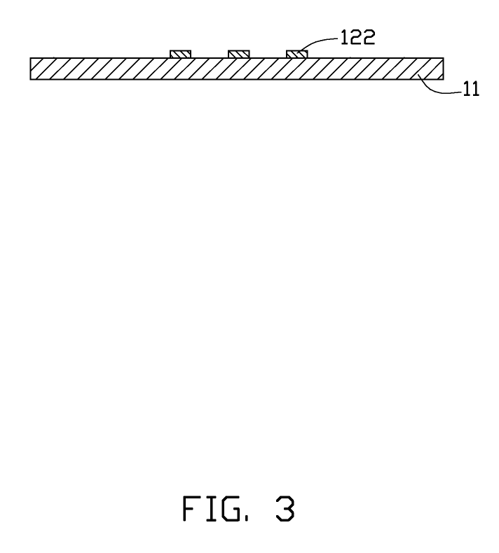

In step 2, referring to FIG. 3, the catalyst blocks 122 are formed on the first layer 11 as follows.

Firstly, a catalyst precursor layer of iron, cobalt, nickel, or alloy thereof, is deposited on a surface of the first layer 11 by electro-deposition, evaporation, sputtering, or vapor deposition.

Secondly, the catalyst precursor layer is oxidized to form a catalyst layer. Specifically, the first layer 11 and the catalyst precursor layer can be sintered in a furnace to oxidize the catalyst precursor layer.

Thirdly, the catalyst layer is patterned using a lithography method and thereby the equidistantly spaced catalyst blocks 122 are obtained. Each catalyst block 122 includes a number of catalyst particles distributed therein. It is noted that the number and distribution of the catalyst blocks 122 correspond to that of the CNT bundles 123.

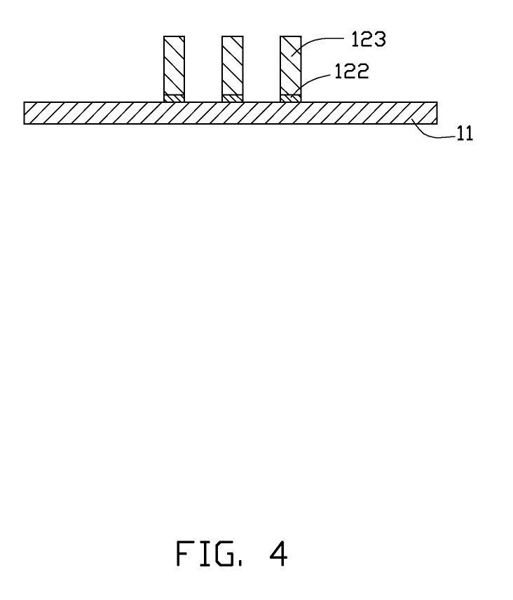

In step 3, referring to FIG. 4, the CNT bundles 123 are formed on the catalyst blocks 122, respectively. In detail, the first layer 11 with the catalyst blocks 122 formed thereon is placed on a carrier boat disposed in a reaction furnace, for example, a quartz tube, wherein the temperature of the reaction furnace is brought to about 700° C. to 1000° C. and carbon source gas such as acetylene and ethylene is introduced into the reaction furnace, causing the CNT bundles 123 to grow from the catalyst blocks 122. The height of the CNT bundles 123 can be determined by controlling the reaction time and an extension axis of the CNT bundles 123 can be controlled with an electric field.

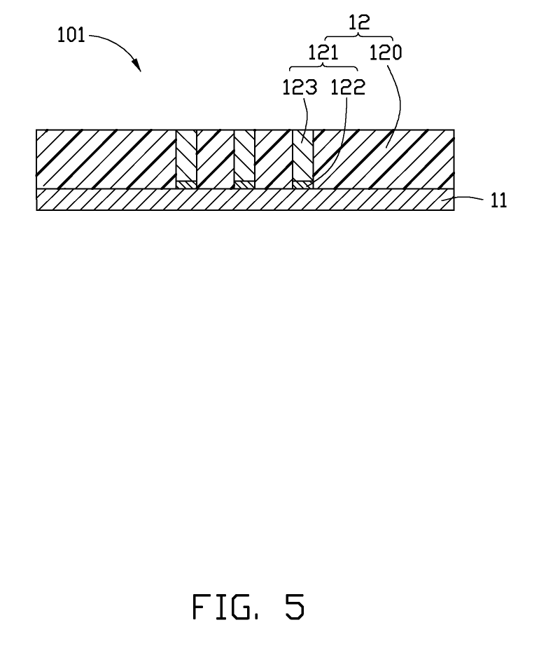

In step 4, referring to FIG. 5, the matrix 120 is formed and thereby the composite layer 12 is obtained by the following. A polymer precursor is spread on the first conductive layer 11, and filled between the catalyst blocks 122 and between the CNT bundles 123. In this embodiment, ultrasonic oscillation is performed during filling of the polymer precursor to thoroughly fill the gaps between the catalyst blocks 122 and between the CNT bundles 123. The polymer precursor is then cured and crosslink reaction occurs in the polymer precursor. Thus the polymer matrix 120 is formed. The matrix 120, the catalyst blocks 122, and the CNT bundles 123 constitute the composite layer 12. The composite layer 12 and the first layer 11 constitute a semi-manufactured substrate 101.

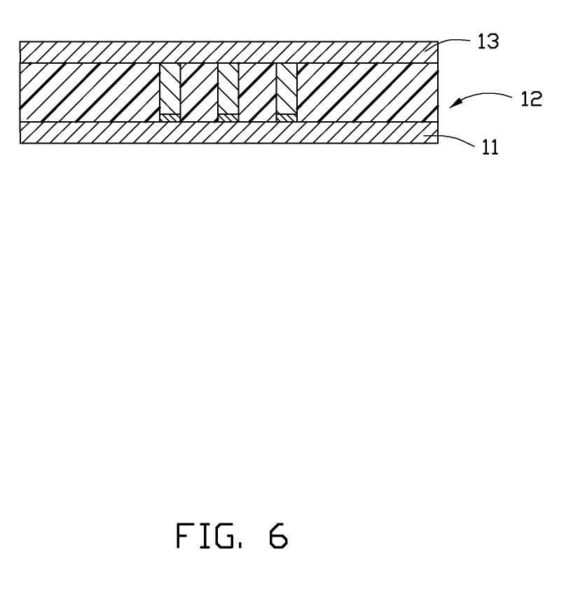

In step 5, referring to FIG. 6, the second layer 13 is adhered onto the composite layer 12. The second layer 13 can be metal such as copper, silver, and nickel.

In step 6, the first layer 11 is processed using a photolithography process and an etching process to form the first pattern 111 therein, meanwhile the second layer 13 is processed to form a second pattern 131 therein. Thus, the PCB 10 as shown in FIG. 1 is obtained.

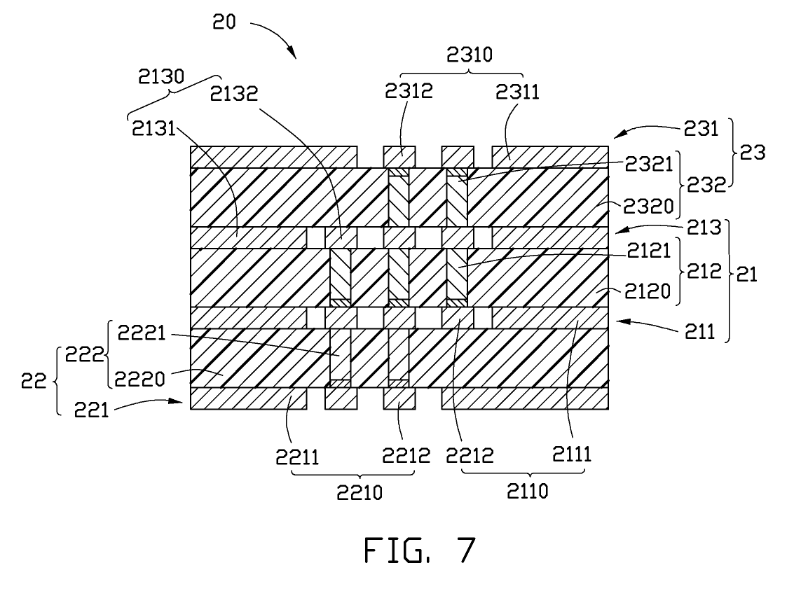

FIG. 7 illustrates a PCB 20 in accordance with a second embodiment. The PCB 20 includes a first circuit substrate 21, a second circuit substrate 22, and a third circuit substrate 23 stacked with each other.

The first circuit substrate 21 has a structure similar to the PCB 10 of FIG. 1, and is sandwiched between the second and third circuit substrates 22, 23. The first circuit substrate 21 includes a first electrically conductive layer 211 having a first electrically conductive pattern 2110 defined therein, a second electrically conductive layer 213 having a second electrically conductive pattern 2130 defined therein, and a first composite layer 212 sandwiched between the first and second conductive layers 211, 213. The first pattern 2110 includes a number of first electrical traces 2111 and a number of first electrical contacts 2112. The second pattern 2130 includes a number of second electrical traces 2131 and a number of second electrical contacts 2132. The second contacts 2132 correspond to the first contacts 2112, respectively. The first composite layer 212 includes a first polymer matrix 2120 and a number of first electrically conductive pins 2121 embedded therein. The first pins 2121 each electrically communicate with one first contact 2112 and one corresponding second contact 2132. The first pins 2121 have structures similar to the conductive pins 121 of FIG. 1.

The second circuit substrate 22 has a structure similar to the semi-manufactured substrate 101 of FIG. 5. The second circuit substrate 22 includes a third electrically conductive layer 221 having a third electrically conductive pattern 2210 defined therein and a second composite layer 222 sandwiched between the first and third conductive layers 211, 221. The third pattern 2210 includes a number of third electrical traces 2211 and a number of third electrical contacts 2212. In the illustrated embodiment, the number of the third contacts 2212 is less than that of the first contacts 2112. Thus, the third contacts 2212 correspond to only some of the first contacts 2112. The second composite layer 222 includes a second polymer matrix 2220 and a number of second electrically conductive pins 2221 embedded therein. The number of the second pins 2221 is equal to that of the third contacts 2212. Each of the second pins 2221 electrically connects to one third contact 2212 and one corresponding first contact 2112.

The third circuit substrate 23 has a structure similar to the second circuit substrate 22. The third circuit substrate 23 includes a fourth electrically conductive layer 231 having a fourth electrically conductive pattern 2310 defined therein and a third composite layer 232 sandwiched between the second and fourth layers 213, 231. The fourth pattern 2310 includes a number of fourth electrical traces 2311 and a number of fourth electrical contacts 2312. In the illustrated embodiment, the number of the fourth contacts 2312 is less than that of the second contacts 2132. Thus, the fourth contacts 2312 correspond to only some of the second contacts 2132. The third composite layer 232 includes a third polymer matrix 2320 and a number of third electrically conductive pins 2321 embedded therein. The number of the third pins 2321 is equal to that of the fourth contacts 2312. Each of the third pins 2321 electrically connects to one fourth contact 2312 and one corresponding second contact 2212.

It is noted that the number of the first or second contacts 2112, 2132 can be less than or equal to the total number of third and fourth contacts 2311 and 2312, therefore, electrical signals from the first circuit substrate 21 can be transmitted to the second or third circuit substrates 22, 23 via the first, second, and third pins 2121, 2221, 2321.

In the illustrated embodiment, the first, second, third, and fourth layers 211, 213, 221, 231 are electrically connected to each other by the first, second, and third pins 2122, 2222, 2322, which have excellent electrical conductivity. Therefore, the PCB 20 has excellent electrical properties.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

1. A printed circuit board, comprising:
a first electrically conductive layer having a first electrically conductive pattern formed therein;
a second electrically conductive layer having a second electrically conductive pattern formed therein; and
a composite layer positioned between the first and second layers, the composite layer comprising a polymer matrix, at least one catalyst block, and at least one carbon nanotube bundle, the at least one carbon nanotube bundle grown on the at least one catalyst block, the at least one carbon nanotube bundle and the at least one catalyst block being both embedded in the polymer matrix, the at least one catalyst block being electrically in contact with the first pattern, the at least one carbon nanotube bundle being electrically in contact with the second pattern.

2. The printed circuit board of claim 1, wherein the first pattern comprises a plurality of first electrical traces and at least one first electrical contact, the at least one catalyst block is in contact with the at least one first electrical contact, the second pattern comprises a plurality of second electrical traces and at least one second electrical contact, the at least one carbon nanotube bundle is in contact with the at least one second electrical contact.

3. The printed circuit board of claim 2, wherein the number of the at least one first electrical contact is equal to the number of the at least one catalyst block, and the number of the at least one second electrical contact is equal to the number of the at least one carbon nanotube bundle.

4. The printed circuit board of claim 1, wherein the composite layer comprises a first surface being in contact with the first electrically conductive layer and a second surface being in contact with the second electrically conductive layer, and the at least one catalyst block is exposed at the first surface, the at least one carbon nanotube bundle is exposed at the second surface.

5. The printed circuit board of claim 4, wherein the at least one carbon nanotube bundle extends from the at least one catalyst block to the second surface at an angle of from 80° to 100° relative to the second surface.

6. The printed circuit board of claim 4, wherein a length of the at least one carbon nanotube bundle is substantially equal to a distance between the first surface and the second surface minus a thickness of the at least one catalyst block.

7. The printed circuit board of claim 1, wherein the at least one carbon nanotube bundle comprises a plurality of carbon nanotube bundles, the at least one catalyst block comprises a plurality of catalyst blocks spatially correspond to the carbon nanotube bundles respectively.

8. The circuit substrate as claimed in claim 7, wherein the carbon nanotube bundles are substantially parallel to and isolated from each other.

9. A printed circuit board, comprising:
a first composite layer comprising a first polymer matrix and at least one first electrically conductive pin embedded therein, the first polymer matrix having a first surface and a second surface at an opposite side thereof to the first surface, the at least one first pin comprising a first catalyst block and a first carbon nanotube bundle grown on the first catalyst block, the first catalyst block exposed at the first surface, the first carbon nanotube bundle exposed at the second surface;
a first electrically conductive pattern formed on the first surface, the first pattern including at least one first electrical contact, which is electrically coupled to the first catalyst block; and
a second electrically conductive pattern formed on the second surface, the second pattern including at least one second electrical contact, which is electrically coupled to the first carbon nanotube bundle.

10. The printed circuit board of claim 9, wherein the number of the at least one first electrical contact is equal to that of the at least one second electrical contact and that of the at least one first pin.

11. The printed circuit board of claim 9, wherein the composite layer comprises a first surface being in contact with the first pattern and a second surface being in contact with the second pattern, and the catalyst block is exposed at the first surface, the carbon nanotube bundle is exposed at the second surface.

12. The printed circuit board of claim 11, wherein the carbon nanotube bundle extends from the catalyst block to the second surface at an angle of from 80° to 100° relative to the second surface.

13. The printed circuit board of claim 9, further comprising a third electrically conductive pattern and a second composite layer positioned between the first and third patterns, the second composite layer comprising a second polymer matrix and at least one second electrically conductive pin embedded therein, the at least one second pin comprising a second catalyst block and a second carbon nanotube bundle grown on the second catalyst block, the second catalyst block being electrically in contact with the third pattern, the second carbon nanotube bundle being electrically in contact with the least one first electrical contact.

14. The printed circuit board of claim 13, further comprising a fourth electrically conductive pattern and a third composite layer positioned between the second and fourth patterns, the third composite layer comprising a third polymer matrix and at least one third electrically conductive pin embedded therein, the at least one third pin comprising a third catalyst block and a third carbon nanotube bundle grown on the third catalyst block, the third catalyst block being electrically in contact with the second pattern, the third carbon nanotube bundle being electrically in contact with the least one second electrical contact.

15. The printed circuit board of claim 14, wherein the number of the at least one first pin is equal to the total number of the at least one second pin and the at least one third pin.

16. The printed circuit board of claim 14, wherein the number of the at least one first pin is less than the total number of the at least one second pin and the at least one third pin.
